(19) United States
(12) Patent Application Publication
(10) Pub. No.: US 2007/0218694 A1
(43) Pub. Date: Sep. 20, 2007

(54) Method of reducing particle count inside a furnace and method of operating the furnace

(76) Inventors: Cheng-Chung Hung, Sinying City (TW); Chiu-Hsien Yeh, Tainan City (TW)

Correspondence Address: J.C. Patents, Inc., Suite 250, 4 Venture, Irvine, CA, 92618, US

(21) Appl. No.: 11/378,868

(22) Filed: Mar. 16, 2006

(51) Int. Cl. H01L 21/302; H01L 21/461

(52) U.S. Cl. 438/704; 438/711

(57) ABSTRACT

A method for reducing particle count inside a furnace for processing semiconductor devices is provided. The method includes performing a gas blowing step to feed a gas into the furnace and performing a continuous gas pumping step simultaneous with performing the gas blowing step for extracting the gas from the furnace while a constant pressure is maintained inside the furnace.

### BACKGROUND OF THE INVENTION

1. Field of the Invention

The present invention relates to a method of cleaning and operating a semiconductor processing apparatus. More particularly, the present invention relates to a method of reducing particle count inside a furnace and a method of operating the furnace.

2. Description of the Related Art

In a highly commercialized semiconductor fabrication process, the polysilicon layer is mostly formed by performing a chemical vapor deposition (CVD) process inside a reaction chamber. For example, to form the desired polysilicon layer, silicane and phosphine are heated and then the dissociated compound are deposited to form the polysilicon layer. Because the CVD process uses chemical reactions to carry out the deposition of thin films, the reaction products will be deposited on the surface of the reaction chamber besides the surface of a wafer. At present, the interior of most polysilicon furnace is fabricated using quartz material. When too much reaction byproducts gets accumulated on the interior sidewall of the reaction chamber, some of the deposited film material may peel off due to the poor adhesion on the quartz surface. In particular, some of the particles adhered close to a nozzle may peel off and remain suspended as contaminants in the gas stream inside the furnace that may undesirably affect the overall yield of wafer deposition. In some serious cases, the whole processing batch may be required to be scrapped.

To prevent particles from contaminating the products and undesirably affecting the yield, the most common method is to increase the frequency of routine preventive maintenance (PM). Alternatively, the increase in particle count after each deposition process is monitored so that the apparatus is re-conditioned when the particle count exceeds a predetermined particle count. The former method affects the uptime of the machine and increases the maintenance cost while the latter method increases the probability of scrapping of a large batch of products.

At present, particle problems are dealt with by executing a cyclic purging process. In other words, the cyclic purging process includes alternately performing a feeding gas step and a circulating the gas step within the furnace after a predetermined usage period of time. A small volume of nitrogen, for example at a flow rate of about 1˜2 standard liters per minute (SLM), particles on the inner walls and nozzles may be reduced to suspension. Thereafter, by applying a vacuum of about 1 torr, the gaseous nitrogen along with the suspended particles may be removed from the furnace. However, this method is little effective for removing particles only but not so effective for removing most drop particles.

### SUMMARY OF THE INVENTION

Accordingly, at least one objective of the present invention is to provide a method for reducing the particle count inside a furnace by removing particles/residues deposited on the inner wall of the furnace or nozzle by using a combination of stress and gas current.

At least another objective of the present is to provide a method of operating a furnace including a method of reducing the particle count within the furnace without suffering the uptime of the furnace.

To achieve these and other advantages and in accordance with the purpose of the invention, as embodied and broadly described herein, the invention provides a method of reducing the particle count inside a furnace for use for a semiconductor process. The method comprises performing a gas blowing step to feed a gas into the furnace and performing a continuous gas pumping step simultaneous with performing the gas blowing step for extracting the gas from the furnace while a constant pressure is maintained inside the furnace.

According to an embodiment of the present invention, the aforementioned gas comprises helium, neon, argon, krypton, xenon, radon or nitrogen, for example. The flow rate of the gas is greater than 20 standard liters per minute (SLM), preferably between 15˜30 SLM.

According to an embodiment of the present invention, the aforementioned constant pressure is maintained, for example, between 200˜600 torrs.

According to an embodiment of the present invention, the gas blowing step includes a continuous gas blowing step, for example. In another embodiment, the gas blowing step includes a non-continuous gas blowing step, for example.

The present invention also provide a method of operating a furnace. The operating method includes the following steps. First, the furnace door is opened and a wafer boat containing at least one wafer is loaded inside the furnace. Next, the furnace door is closed and the reactions are performed on the wafer. After the completion of the reaction on the wafer, the furnace door is opened and the wafer boat is unloaded from the furnace. Thereafter, the furnace door is closed again and then a cleaning process is carried out inside the furnace to clean the interior of the furnace. The cleaning process comprises performing a gas blowing step to feed a gas into the furnace and performing a continuous gas pumping step simultaneous with performing the gas blowing step for extracting the gas from the furnace while a constant pressure is maintained inside the furnace.

According to an embodiment of the present invention, the aforementioned gas comprises helium, neon, argon, krypton, xenon, radon or nitrogen, for example. The feeding flow rate of the gas is, for example, greater than 20 SLM, preferably between 15˜30 SLM.

According to an embodiment of the present invention, the aforementioned constant pressure is, for example, between 200˜600 torrs.

According to an embodiment of the present invention, the aforementioned gas blowing step comprises a continuous gas blowing step. In another embodiment, the gas blowing step comprises a non-continuous gas blowing step.

In the present invention, the cleaning process for reducing the particle count inside the furnace includes performing a gas blowing step and performing a continuous gas pumping step simultaneously. The aforementioned gas blowing step enables a large volume of gas under pressure is blowed into the furnace so that any deposited film material or residues deposited on the nozzle (or on the air inlet tube) may be dislodged or peeled off therefrom. Meanwhile, the continuous gas pumping step enables a constant pressure is maintained inside the furnace. When the gas passes by the nozzle (or the gas injection tube) in the interior of the furnace, impinges on the nozzle (or the gas injection tube) and removes any film material or residues deposited on the nozzle (or the gas injection tube). Furthermore, the feeding and continuous removal of the gas from the interior of the furnace maintains a constant flow density inside the furnace for churning up particles and transporting the suspended residues out of the furnace. Thus, the particles/residues may be effectively removed from the furnace. Moreover, the method of the present invention may be integrated into the wafer fabrication process in order to reduce the number of contaminating particles/reduces floating inside the furnace during the time period between the unloading of the wafer boat and loading of the wafer boat. Accordingly, the uptime of the processing station is unaffected so that the production throughput is unaffected.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a flow diagram showing the steps of operating a furnace according to an embodiment of the present invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

The method of the present invention may be applied to a vertically mounted and a horizontal mounted furnace. In general, the method of the present invention may be effectively applied on any type of furnace and is particularly suitable for a furnace used for polysilicon deposition process.

The method of the present invention is used for reducing the particle count inside a furnace used for a semiconductor process. The method includes simultaneously performing a gas blowing step and a continuous gas pumping step. The foregoing gas blowing step includes blowing a gas into the furnace. The gas comprises helium, neon, argon, krypton, xenon, radon or nitrogen, for example. Alternatively, any other type of gas may also be used as long as it does not interfere with the reaction process. The flow rate of the gas may be greater than 20 standard liter per minute (SLM), preferably between about 15˜30 SLM. Thus, when the gas is blowed via the nozzle (or the gas injection tube) into the furnace, the flow of a large volume of gas under pressure is capable of removing any film material or residues deposited on the nozzle (or the gas injection tube). Thus, the method of the present invention may effectively reduce the particle count inside the furnace so that the possibility of film material or residues from contaminating the wafer during the deposition reaction may be effectively reduced and therefore the fabrication yield can be effectively promoted.

In addition, the foregoing continuous gas pumping step to extract gas from the furnace is carried out simultaneously with the gas blowing step. The continuous gas pumping step serves to maintain a constant pressure inside the furnace. The constant pressure inside the furnace may be between 200˜600 torrs, for example. The particles/residues removed from the interior wall of the furnace during the continuous gas pumping step may remain suspended in the gas current inside the furnace and then removed from the furnace along with the gas being continuously pumps out of the furnace.

It should be noted that the method of the present invention is different from the conventional alternately purging and circulating the gas inside the furnace. During the cleaning process according to the present invention, the gas is blowed into the furnace and the gas is continuously removed from the furnace and a constant pressure is maintained inside the furnace. As the gas pass past the nozzle (or the gas injection tube) within the furnace, the gas impinges on the surface of the nozzle (or the gas injection tube) and removes any film material or residues deposited on the nozzle (or the gas injection tube). Furthermore, the large volume of the gas continuously pumped or blowed into the furnace is sufficient gas to suspend the particles within the furnace and the suspended particles are removed along with the gas being continuously pumped out of the furnace.

In one embodiment of the present invention, the aforementioned gas blowing step is a continuous gas blowing step, for example. In another embodiment of the present invention, the aforementioned gas blowing step is a non-continuous blowing step, for example. In other words, the method of reducing the particle count inside the furnace may include, for example, the simultaneous performance of a gas blowing step and a continuous gas pumping step. Alternatively, the method of reducing the particle count inside the furnace may include, for example, the simultaneous performance of a non-continuous gas blowing step and a continuous gas pumping step.

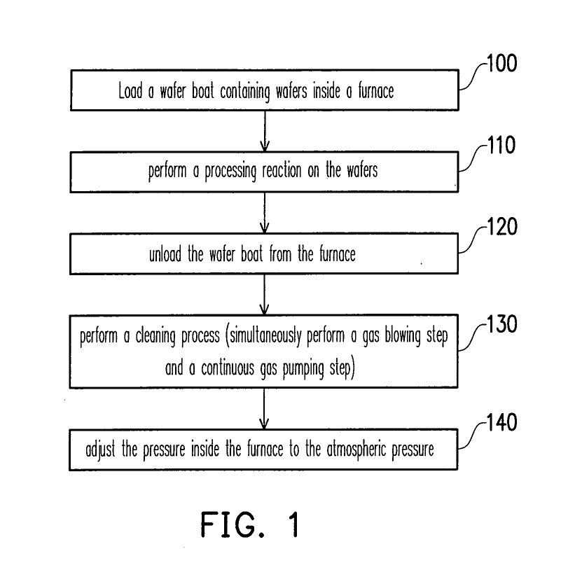

In addition, the method of reducing the particle count inside the furnace described above may be incorporated into the wafer fabrication process. Hereinafter, a method of operating the furnace is described with reference to FIG. 1 according to an embodiment of the present invention as follows.

As shown in step 100 in FIG. 1, a wafer boat carrying a batch of wafers is transferred into a furnace. Step 100 includes opening the furnace door and placing the wafer boat inside the furnace.

At step 110, a processing reaction on the wafers is carried out. The processing reaction includes depositing a polysilicon layer on the wafers or any other semiconductor fabrication process. Step 110 includes closing the door of the furnace and initiating the processing reaction on the wafer.

At step 120, the wafer boat is unloaded from the furnace. Step 120 includes waiting until all the processing reaction on the wafers is complete and stopped, opening the door of the furnace and removing the boat load of wafers out of the furnace.

Thereafter, the furnace door is closed again to perform step 130. At step 130, a cleaning process is performed to reduce the particle count inside the furnace. The cleaning process includes blowing a gas into the furnace and continuously pumping the gas out of the furnace simultaneously.

The aforementioned gas comprises helium, neon, argon, krypton, xenon, radon or nitrogen, for example. Alternatively, any other type of gas may also be used as long as it does not interfere with the reaction process. The gas may be blowed into the furnace at a flow rate greater than 20 SLM, preferably between about 15˜30 SLM. In one embodiment of the present invention, the flow rate of the gas is about 26 SLM, for example. Furthermore, as the gas is being continuously blow into the furnace, the gas is continuously pumped out of the furnace such that a constant pressure, for example 200-600 torrs, is maintained within the furnace. In one embodiment of the present invention, the constant pressure is about 320 torrs, for example.

After the completion of the cleaning process, the pressure within the furnace is adjusted to about 760 torrs (step 140). That is, the furnace is subjected to the atmospheric pressure for carrying out the next processing reaction.

Accordingly, the method of the present invention provides an effective means of removing particles or residues deposited inside the furnace and thereby significantly reduce the particle count therein. In particular, the cleaning process may be carried out during the time period after the unloading of the wafer boat from the furnace and before loading the wafer boat with the next batch of wafers. Hence, the purging process of the present invention will not affect the throughput of the furnace.

In summary, the present invention provides at least the following advantages.

1. A large volume of gas is blow under pressure into the furnace to dislodge any particles or residues deposited on the nozzle (or the gas injection tube) and removed from the furnace.

2. The continuous pumping of gas out of the furnace causes a gas current inside the furnace and makes the gas continuously impinge on the nozzle (or the gas injection tube) so that any film material or residues deposited on the nozzle (or the gas injection tube) may be effectively removed. Furthermore, by providing sufficient gas density and flow inside the furnace, particles or residues are suspended in the gas current and are carried out of the furnace along with the gas being pumped out and thereby reduce particle count inside the furnace.

3. By blowing gas inside the furnace and continuously removing the gas out of the furnace, the particle count inside the furnace can be reduced to a minimum.

4. The method of reducing the particle count inside the furnace may be integrated into the wafer fabrication process in such a way that neither the uptime of the processing station nor the throughput is affected.

It will be apparent to those skilled in the art that various modifications and variations can be made to the structure of the present invention without departing, from the scope or spirit of the invention. In view of the foregoing, it is intended that the present invention cover modifications and variations of this invention provided they fall within the scope of the following claims and their equivalents.

What is claimed is:

1. A method of reducing particle count inside a furnace used for a semiconductor process, comprising:
performing a gas blowing step to feed a gas into the furnace; and
performing a continuous gas pumping step simultaneous with performing the gas blowing step for extracting the gas from the furnace while a constant pressure is maintained inside the furnace.

2. The method of claim 1, wherein the gas comprises helium, neon, argon, krypton, xenon, radon or nitrogen.

3. The method of claim 1, wherein a flow rate of the gas blowed into the furnace is greater than 20 standard liters per minute.

4. The method of claim 1, wherein a flow rate of the gas blowed into the furnace is between 15 to 30 standard liters per minute.

5. The method of claim 1, wherein the constant pressure is between 200 to 600 torrs.

6. The method of claim 1, wherein the gas blowing step comprises a continuous gas blowing step.

7. The method of claim 1, wherein the gas blowing step comprises a non-continuous gas blowing step.

8. A method of operating a furnace used for a semiconductor process, comprising:
opening a door of the furnace and loading a wafer boat comprising at least one wafer inside the furnace;
closing the door of the furnace and performing a processing reaction on the wafer;
opening the door of the furnace after the completion of the processing reaction on the wafer and unloading the wafer boat from the furnace;
closing the door of the furnace and performing a cleaning process to reduce particle count inside the furnace, the cleaning process comprising:
performing a gas blowing step to feed a gas into the furnace; and
performing a continuous gas pumping step simultaneous with performing the gas blowing step for extracting the gas from the furnace while a constant pressure is maintained inside the furnace.

9. The operating method of claim 8, wherein the gas comprises helium, neon, argon, krypton, xenon, radon or nitrogen.

10. The operating method of claim 8, wherein a flow rate of the gas blowed into the furnace is greater than 20 standard liters per minute.

11. The operating method of claim 8, wherein a flow rate of gas blowed into the furnace is between 15 to 30 standard liters per minute.

12. The operating method of claim 8, wherein the constant pressure is between 200 to 600 torrs.

13. The operating method of claim 8, further comprising a step of adjusting the pressure inside the furnace to one atmosphere pressure after the cleaning process and before the next reaction.

14. The operating method of claim 8, wherein the gas blowing step comprises a continuous gas blowing step.

15. The operating method of claim 8, wherein the gas blowing step comprises a non-continuous gas blowing step.
